(19) United States
(12) Patent Application Publication
(10) Pub. No.: US 2021/0358785 A1
(43) Pub. Date: Nov. 18, 2021

(54) EVENT MONITORING AND CHARACTERIZATION

(71) Applicant: Advanced Energy Industries, Inc., Fort Collins, CO (US)

(72) Inventors: Andrew Merton, Fort Collins, CO (US); Jeffrey Harrell, Fort Collins, CO (US); Brian D. Kowal, Fort Collins, CO (US)

(21) Appl. No.: 17/318,326

(22) Filed: May 12, 2021

Related U.S. Application Data
(60) Provisional application No. 63/023,724, filed on May 12, 2020.

(51) Int. Cl. H01L 21/67; G06N 3/08; H01J 37/32

(52) U.S. Cl. CPC H01L 21/67276; G05B 19/41875; H01J 37/32944; G06N 3/08

(57) ABSTRACT

A system, method and software for generating and receiving information about the AC, DC, RF, voltage, and other characteristics and information provided by components in a system. The information can provide insight into the operational characteristics and functionality of the components, as well as the process and system the components are being used within. This information may be used for preventative maintenance of the components, and to detect changes, issues, failures, events, problems, etc. in the process and system.

### CLAIM OF PRIORITY UNDER 35 U.S.C. § 119

The present application for patent claims priority to Provisional Application No. 63/023,724 entitled “SENSORLESS ARC MONITORING AND CHARACTERIZATION” filed May 12, 2020 and assigned to the assignee hereof and hereby expressly incorporated by reference herein.

### FIELD OF THE DISCLOSURE

The present disclosure relates generally to information produced or provided by power sources, power supplies, match networks, and generators, and more specifically to the use of the produced information to better analyze the load connected to the component(s), and analytics to optimize maintenance of component(s).

### BACKGROUND

In industrial and other applications, power sources, power supplies, match networks, and generators (“components”) are used in a variety of manufacturing processes. The component(s) provide alternating current (AC), radio frequency (RF) power, direct current (DC), various voltages, controls, and functionality for the variety of processes. These processes may include highly technical and controlled processes, such as thin film coating, and other precision processes and systems.

Manufacturers may want more information about the precision processes and systems. Currently, they have limited information on events such as arcing in the process, which can create defects in what is being produced. The level of information makes it challenging to determine the level of severity and significance of the arc event. Current systems can add supplemental sensing which may include physical sensors within the system to sense characteristics of the process. Physical sensors may change the nature of the process and may not be useable in certain processes.

Manufacturers may also want to prevent failures with the component(s) and the processes. In current approaches, preventative maintenance on components may be administered at regular intervals so it will continue to provide the required performance, including minimizing arc related defects. Removing a component for preventative maintenance can result in significant expense, so there is desire to maximize time between preventative maintenance intervals. But if preventative maintenance intervals are too far apart, the risk of degradation to the point where service is required increases, which is often more costly than preventative maintenance. Current approaches for timing preventative maintenance are not optimized; thus, there is a need in the art for ways to optimize and schedule preventative maintenance events.

### SUMMARY

Information about the AC power, DC power, voltage, current, and other characteristics and information provided by components can provide insight into the operational characteristics and functionality of the components, as well as the process and system the components are being used within. This information may be used to detect changes, issues, failures, problems, etc. in the process and system. This information may also be used to inform preventative maintenance of the components.

The system may comprise a computing device configured to receive the data from the data acquisition device, analyze the data, and determine, based on analysis of the one or more operating characteristics and the plurality of system fault events, an event definition, an event identification, event information and characteristics, and an event notification. The system may provide the notification to a user. The notification may include enough information for the user to understand the event, time, segment, process, where to look for defects in materials and components, and to assist the user in determining if the materials should be used, repaired or scrapped, and if the component is malfunctioning and in need of repair.

Another aspect of the disclosure provides a method for optimizing the process and/or the system of which a component is a part. The method may comprise recording data from a component. The data may comprise measurements of one or more operating characteristics of the component over a period of time and a plurality of indications of system fault events. The method may include receiving the data; analyzing the data; and determining, based on correlations between the measurements of the one or more operating characteristics and the plurality of system fault events, a threshold of an operating point. The operating point may comprise the measurements of the one or more operating characteristics at a particular time. The threshold may signify a pending system fault event is probable to a defined degree of confidence within a specified window of time. The method may comprise providing a notification of an event and various characteristics of the event.

Another aspect of the present disclosure provides a system for optimizing component maintenance. The system may comprise a component and a data acquisition device connected to the component and configured to record data. The data may comprise measurements of one or more operating characteristics of the component over a period of time, which may be used for maintenance and other reasons for the component, system, and the process, including process fault events.

Yet another aspect of the disclosure provides a non-transitory, tangible computer readable storage medium, encoded with processor readable instructions to perform a method for optimizing maintenance of a component. The method may comprise recording data from a component. The data may comprise measurements of one or more operating characteristics of the component over a period of time and a plurality of indications of component, process, and/or system fault events. The method may include receiving the data; analyzing the data; and determining, based on analyzing the measurements of the one or more operating characteristics and the plurality of component, process, and/or system fault events, a threshold of an operating point. The operating point may comprise the measurements of the one or more operating characteristics at a particular time. The threshold may signify a pending component, process, and/or system fault event is probable to a defined degree of confidence based at least in part on the analysis of the characteristics of the event. The method may comprise providing a notification of a fault, pending fault, issue with the process or system, etc.

### BRIEF DESCRIPTION OF THE DRAWINGS

FIG. 1 is a block diagram illustrating an example component upstream of a plasma processing chamber within a system, according to an embodiment.

FIG. 2A is a graph is a graph plotting power output from a generator used to control a primary process chamber.

FIG. 2B is a graph depicting an example of voltage and current traces captured during an arc event.

FIG. 3A depicts data comprising operating characteristics used for creating predictive analytics according to the present disclosure.

FIG. 3B depicts raw and filtered data measuring a parameter that increases over time in relation to a threshold and a component, process, and/or system fault event.

FIG. 3C depicts raw and filtered data measuring a parameter that decreases over time in relation to a threshold and a component, process, and/or system fault event.

FIG. 4 shows an N-dimensional parameter space divided by a hyperplane with a nominal dimension of N−1.

FIG. 5 is a network architecture diagram depicting components of a predictive analytics system of the present disclosure.

FIG. 6 is a flowchart depicting a method of the present disclosure.

FIG. 7 is a block diagram depicting a pulsed-DC power supply as an example of a system component.

FIG. 8 is a block diagram depicting an example of an application of the pulsed-DC power supply of FIG. 7.

FIG. 9 is a graph depicting examples of voltage and current operating characteristics of the pulsed-DC power supply depicted in FIG. 8.

FIG. 10 is a graph depicting examples of voltage and current operating characteristics and configuration parameters of the pulsed-DC power supply of FIG. 8.

FIG. 11 is a block diagram depicting an RF generator as another example of a system component.

FIG. 12 is a block diagram depicting a match network as yet another example of a system component.

FIG. 13 is a diagram depicting a neural network as an example of an approach to modeling aspects of components.

FIG. 14 is a flowchart depicting a method for troubleshooting and addressing issues with a component.

FIG. 15 is a computing environment, which may be used to implement aspects of the present disclosure.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Arcing may occur within a plasma chamber when a plasma generator is providing power to produce plasma. These can occur in a variety of industrial and semiconductor processes. These processes can include physical vapor deposition (PVD), chemical vapor deposition (CVD), etching and other processing in a plasma chamber.

PVD, CVD, and etch or other systems are configured to process a substrate, including adding or removing material on a substrate, for example. Arcing may occur at various locations in the plasma chamber, including on or near the substrate. Arcing can occur between plasma and the chamber wall, or substrate, which can create particulate matter and can cause errors in the process and defects with the substrate.

Components may be used in various tasks in the process, including as a source for creating the plasma, or supporting the process, such as biasing the chuck and/or substrate, or powering a coil with a RF or DC source. The components can detect and attempt to suppress events such as arcing events, and can provide information about arcing events.

In one embodiment, a system and method for the monitoring and quantifying arc events in physical vapor deposition (PVD) semiconductor manufacturing processes is described. This approach differentiates itself from traditional monitoring techniques, where additional sensors would need to be installed into the process chamber to monitor the arcing event, by leveraging the onboard capabilities of the power generator. In this approach, information from one or more power sources are collected, such as a DC power supply generator, which provides the energy to ignite and sustain the plasma in the PVD process. This information is collected over a period of time and contains the operating characteristics and plurality of system fault indicators.

A method may include receiving information from power sources; analyzing the information to determine the magnitude and severity of the arcing event; and reporting the analysis results and other information to the primary operating or control system. A figure of merit indicating magnitude and severity of arcing quantifying the scale of the event may be used to make quality control decisions including, but not limited to, flagging the product (e.g., wafer) being serviced at the time of the event for inspection or other quality control check. The method may be configured to report additional event characteristics and/or provide long-term trend analysis that maps arc events against operating characteristics or preventative maintenance events (e.g., target material quality and lifetime).

Numerous industrial applications use components in manufacturing of semiconductors, thin-film devices, and other products made with plasma processing chambers. Such applications typically involve components connected and supplying the source power to the plasma processing chamber (the “primary processing chamber”) in which the product is being fabricated. Applications include using components to supply power, control, modify, etc. various industrial processes, including a plasma processing chamber.

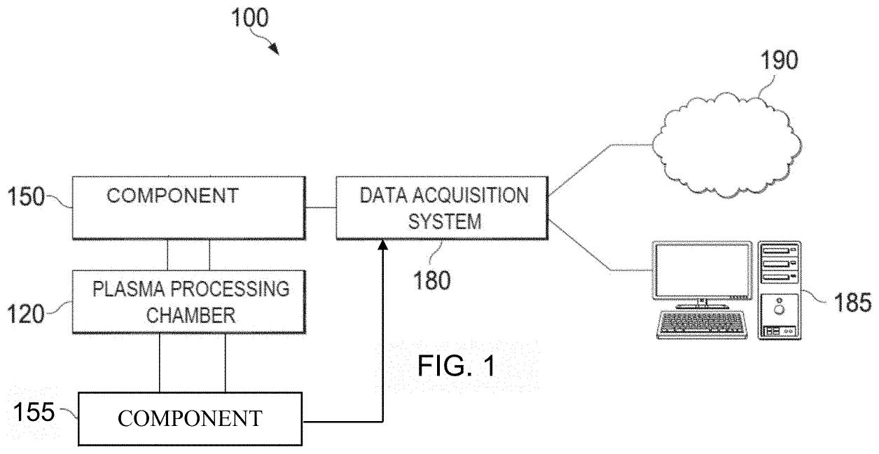

FIG. 1 for example, shows a simple block diagram of a system 100 having components 150, 155 connected to the primary processing chamber 120. In this embodiment, system 100 may be a plasma processing system 100 utilized for deposition and/or etch processing. In an embodiment, component 150 may include remote plasma sources, power sources (e.g., RF generators and/or DC generators), power supplies, match networks within a plasma processing system or process. In some variations, additional components are utilized and connected to elements of the primary processing chamber 120 or system to support the process, such as a substrate bias or coil power. For example, these additional components can also monitor performance of the process and correlate with the data collected from the component 150 (e.g., source generator or match network). In such cases, an additional component 155, such as a bias generator, as shown in FIG. 1 may be used.

As will be described more thoroughly through the disclosure, the components 150, 155 are connected to a data acquisition system (or “data acquisition device”) 180. The data acquisition system 180 may be connected to one or more computing devices, including computing device 185, which may be local, edge, and/or a remote computing device (e.g., a remote cloud server) 190. As a specific example, the component 150 may comprise an RF power generator and match network that are collectively designed and operated to ignite and sustain a plasma in the plasma processing chamber 120 and the component 155 may comprise a bias generator that is designed and configured to apply one or more bias voltage(s) to one or more corresponding electrodes within the plasma processing chamber 120. The one or more electrodes may be positioned in close proximity to a substrate support within the plasma processing chamber 120 and the one or more electrodes may also be positioned at other locations within the plasma processing chamber (e.g., to control plasma density).

The data acquisition system 180 may comprise sensors for sensing and memory for buffering values of operating characteristics from the components 150, 155. And the data acquisition system may stream the operational parameter values to controller the computing device 185 and/or the remote computing device 190. In some implementations, the data acquisition system 180 may also comprises an analog to digital converter to convert analog signals received from its various sensors into digital signals to be provided to the computing device 185 and/or the remote computing device 190. The data acquisition system 180 may also receive user definable inputs, which may be, for example, threshold settings of the various sensors of the data acquisition system 180.

In FIG. 1, the data acquisition system 180 is depicted as a single block for ease of depiction, but the data acquisition system 180 may be a distributed system that is implemented across, and integrated with, multiple components such as components 150, 155. When implemented as an integrated portion of one or more of the components 150, 155, the data acquisition system 180 may receive parameter values from sensors that are inherent with the components 150, 155 such as voltage sensors, current sensors, directional couplers and VI sensors, and the data acquisition system 180 may utilize metrology components inherent within the components 150, 155 to sample, convert (e.g., convert from an analog representation to a digital representation) buffer, and store (at least temporarily) parameter value information.

It is also contemplated that the data acquisition system 180 may be implemented as one or more separate devices that are configured to receive (e.g., via low voltage analog conductor-coupling and/or digital bus) information indicative of operating characteristics. When implemented as one or more separate devices, the data acquisition system 180 may simply receive measurements of one or more operating characteristics of the components 150, 155 over a period of time, or the separate devices may include sensors and sampling hardware to generate measurements of the one or more operating characteristics.

The analysis of the information received from a component (such as components 150, 250) may be performed by the computing device 185 and/or the remote computing device 190 and may also comprise characterizing or identifying what type of an event has occurred. This may include, without limitation, an arc in the plasma processing chamber 120, an over voltage event, low voltage event, ignition, instability, fault or other event as discussed further herein. In addition to event-triggered data collection, information obtained from the components 150, 250 may comprise standard data obtained by polling at periodic and ongoing intervals.

In one embodiment, an industrial process may be divided into time segments. The time segments may be defined differently for different processes and each time segment may have different characteristics and information which may be used to identify events and trends. The information received from a components 150, 155 may include information about an event, which may have occurred in the chamber or other portion of the system, within the time segment.

Event information from a component, such as arc-event information that may comprise energy delivered, voltage, current, power, power max and min, process segment, process recipe, number of hard arcs, number of microarcs, hard arc density, micro arc density, impedance, severity of arcs, total energy, and others may be monitored over one complete cycle of a process. Segment transition may be defined when the component is not supplying power (e.g., idling for 30 seconds). The segments of this process may then be defined as time periods between idle events. The segment may correspond to a “recipe” for a process, such as deposition of a thin film on a substrate. Each time segment in the process may be monitored for the same or different characteristics to determine if an event has occurred, and at what time in the process and segment. The information may then be analyzed, and output information may be presented to the end user.

By way of example without limitation, the event may be an arc in a plasma chamber, and the component 150 may be a plasma generator. In this example, the output information may include information about the process segment, such as duration of the segment, maximum power setpoint, maximum output power reading, maximum output current reading, maximum output voltage reading, number of hard arcs, number of micro arcs, maximum hard arc density, maximum micro arc density, additional summary statistics for output power, voltage, current and impedance at fixed power setpoint levels, and other information.

The output information may also include information about an arc event, including hard arc density, micro arc density, time from start of process segment, time from last power setpoint change, time from last power setpoint change, power setpoint, output power reading, output current reading, output voltage reading, estimated impedance, arc description: {‘ignition’, ‘steady state’}, duration of event in nano- or micro-seconds, power setpoint statistics, output power statistics, output current statistics, output voltage statistics, total energy of arc (normalized), one or many shape parameters, time to detect arc, time to initiate control (to squelch arc), time to extinguish arc, and others. The output information may assist the end user in determining what to do with components, materials or substrate within the process.

The output information may also include information about multiple arc events that happen in succession within a single process segment including the number of events, statistics describing the relative time between said events, and statistics describing the component's control responses to the events.

The received information may generally be high resolution (i.e., 10-100 MHz). In the embodiment where the event is an arc, the user may want to see the time, duration, segment, and severity of the arc. If, for example, the energy of the arc exceeds a configurable or dynamic threshold, the user can be notified of the event and its magnitude to allow the user to perform corrective actions, such as where to look for a defect, and what should be done with a wafer in process when the arc occurred, such as repair, scrap, etc.

In many embodiments, the components 150, 155 and/or the data acquisition system 180 may report a plurality of power measures and fault and event indicators, at both low and high temporal resolutions, from which numerous features and metrics may be extracted which, in turn, may be used to calibrate statistical models for component or process health KPIs. First, data features and metrics may be extracted from the low resolution data to characterize individual process segments (each of which may span ones to tens of seconds). Second, high resolution data may be used to quantify or characterize events within each process segment (many of which may not exceed five microseconds in duration). Third, the features and metrics from both the low and high resolution data may be stored within a historian module. Fourth, the analytics module may be configured to consume the feature data to (re-)calibrate statistical models designed to evaluate and forecast either or both component or process health KPIs. Modeling techniques include, but are not limited to, generalized linear models, smoothing procedures, linear and non-linear optimization, machine learning, cluster analysis, etc. Finally, the user may be notified of the current estimated and projected KPI values.

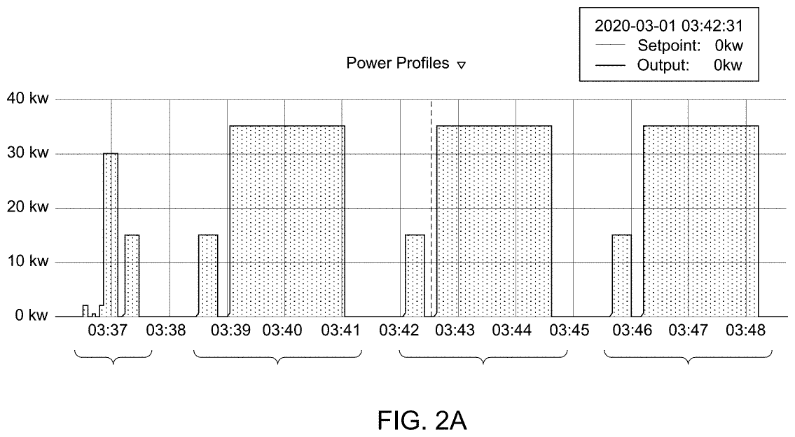

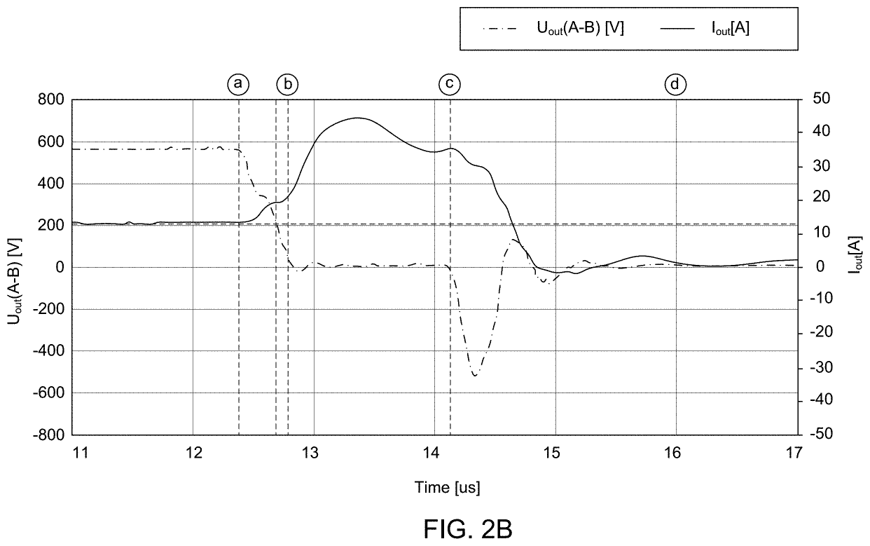

Shown in FIG. 2A is a graph plotting power output from a generator used to control a primary process chamber such as the plasma processing chamber 120. As shown, the graph spans approximately 15 minutes in duration and shows four process segments. According to an exemplary method, a set of features from each segment is extracted and stored so that it can be presented/analyzed in search of trends and correlations over time, throughput, etc. A partial list of features includes:
a. Segment starting & ending timestamps [UTC] and duration [s]
b. Total energy delivered [kJ]
c. Maximum power setpoint [kW], output power [kW], voltage [V] and current [A]
d. No. and maximum density [arcs/s] of hard- and micro-arcs
e. Estimated impedance [R] of the process chamber

In some modes of operation, the high-resolution data may be captured when an event is detected. FIG. 2B comprises a graph that is an example of voltage and current traces captured during an arc event. As shown, the algorithms and methods may receive voltage, current, and power profiles at 10-100 nano-second resolution and compute various event metrics that may include, but are not limited to:
a. Duration (d−a) [s]
b. Voltage [V], current [A] and power [kW] event summary statistics such as mean, standard deviation, quartiles, etc.
c. Energy [kJ] (via numerical integration; ‘area under the curve’)
d. Shape parameters (one or many values such as slopes, extrema, etc.) [-]
e. Configuration parameters (for arc detection & suppression)
f. Detection time (b−a) [s]
g. Reaction time (c−b) [s]
h. Time to extinguish arc (d−c) [s]

The event information and characteristics may be stored within a history datastore of local or remote memory (e.g., within the computing device 185 and/or remote computing device 190). Some of the event information may be forwarded to the user in a configurable alert via the notification engine (e.g., email or via notifications on a mobile device app). The contents of the notification may be configurable to meet different user needs. The user may receive more information, such as analyzed information, to help the user determine next steps.

Additional fields may be added to the event information that reflect the status of the generator (or process) at, just prior to, during, and after the event. Examples of event information may include power setpoint [kW], output power [kW], voltage [V] and current [A], total number of power cycles to date (a.k.a., runs), energy output to date, and/or other information.

The historical data may then be analyzed to search for trends or correlations across events. Examples include applying generalized linear models and/or principal component analysis to identify significant factors, clustering algorithms (e.g., k-means) to group similar events, and other numerical and analysis techniques.

Furthermore, the information received from the device may also include an event or trend which may indicate preventive maintenance may be required. Preventative maintenance is more desirable than addressing system faults. A “system fault,” as defined in this disclosure, is any event significant enough to require some kind of corrective maintenance, such as unplanned cleaning, refurbishment, or replacement of components. System fault events requiring unplanned cleaning, refurbishment, or replacement may be significantly more costly, both in time and money, than preventative maintenance. A system fault event can be extremely problematic when it occurs unexpectedly, because the component is typically part of a larger manufacturing process of highly sensitive and costly products.

Components 150, 155 can report real-time operating characteristics, such as voltage, current, phase between the AC voltage and current driving at the coil or electrode, temperature, impedance, and other measurements. In other words, it may be equipped with multiple measurement output mechanisms for such characteristics, because these characteristics may be used for interacting with the plasma processing system and process to which it is connected.

In embodiments of the present disclosure, the component 150, 155 may be outfitted to implement the data acquisition system 180, the data acquisition system 180 configured to record multiple real-time operating characteristics of the component 150, 155. It is contemplated that any type of measurable output from the component 150, 155 may be measured and recorded by the data acquisition system 180, such as the voltage, current (either DC or AC), temperature, and impedance described above. Temperature, in particular, may be measured at multiple sensors, including thermistors and thermocouples, at different places throughout the component 150, 155, system, and process. Long-term monitoring of temperature may be especially important in generating the predictive analytics of the present disclosure, because initial operating temperatures for different systems, even those created by the same manufacturer, can have high variability due to variations in slope and offset in the temperature sensors at the time of manufacture.

It is also contemplated that the data acquisition system 180 may record other measurable output from components of the plasma processing system to which a component is connected. For example, in some applications, plasma processing is used in conjunction with cooling water systems. In order to maximize the efficiency of such systems, measurements of flow rate, inlet and outlet temperatures, and water pressure may be taken or calculated. In some applications, characteristics of gas utilized within the plasma processing systems may be measured. These include gas flow rates, gas pressures inside chambers, and actual compositions of gasses.

As previously described, the data acquisition system 180, in many embodiments, is configured to be connected to one or more local computing devices 185 and/or one or more remote computing devices 190 via a network, and to send its recorded data thereto. The data acquisition system 180 and the network components to which it is connected may be referred to as the “analytics system” of the present disclosure. It is contemplated that the data acquisition system 180 may collect, record, and send any measurable operating characteristics, and that an analytics portion of the system, implemented at computing devices 185, 190, may calculate measurement parameters based thereon. These calculated measurement parameters (also referred to herein as “indirectly derived parameters” may include a variety of measurements, depending on the configuration of the component; some examples of these indirectly derived parameters may be: slope of current, voltage, or power during an event, area under the curve, or plasma and chamber impedance.

However, calculated measurement parameters may include any metric that is not directly measured, but is rather derived from other directly measured characteristics. Another possible measurement is the degree of capacitive coupling compared to inductive coupling. Many plasma processing applications are intended to work through inductive coupling processes. However, in certain applications, the physics of the plasma is such that capacitive coupling can become dominant, which may be undesirable for several reasons, including that capacitive coupling may increase the rate of material buildup upon, or material sputtering from, the chamber walls.

In some embodiments, certain operating parameters which are not directly measured may be estimated (i.e., by calculations) from other directly measured operating characteristics. These may include the phase of the power delivery waveform, and the capacitance or thickness of the walls of the chamber itself. In other embodiments, these calculated measures may be directly measured.

In embodiments of the disclosure, the data acquisition system 180 may record operating characteristics of a particular component in a particular application over time. For example, one data acquisition system 180 may be locally connected (e.g., through a short cable, or on a local area network (LAN)) to the components 150, 155 within the system 100. The operating characteristics of a particular component 150, 155 may be collected over time and analyzed by a connected computing device 185, 190 in relation to the occurrence of preventative maintenance events and system fault and other events.

In an embodiment, based on patterns of correlation between particular measurements and the system fault events, the computing device may, over time, create models of these operating characteristics that show when a system fault event is likely to occur. In certain applications, it is known that preventative maintenance should be performed at least every few days, and in others, every few weeks.

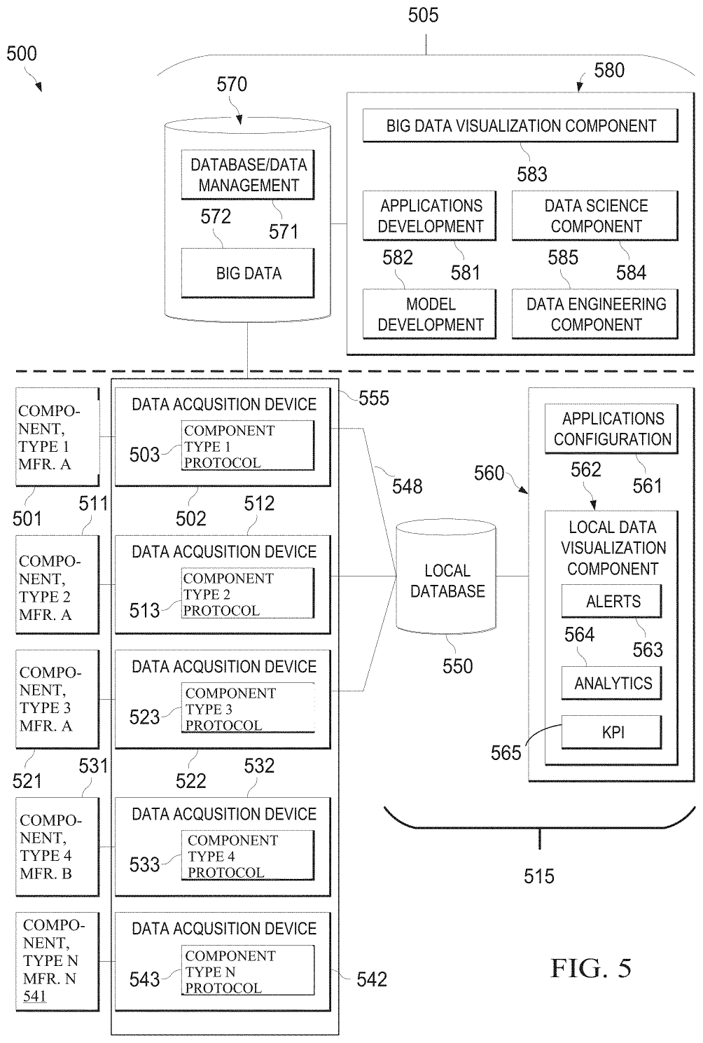

However, the more data that can be collected about a particular type of component 150, 155 used in a particular application, the more quickly and accurately predictions may be made. If, for example, a single manufacturer of thin films uses dozens of similar components 150, 155, the connected data acquisition system(s) 180 may collect many more instances of preventive maintenance and system fault events in a shorter period of time. In embodiments of the present disclosure, such operating characteristics may be collected from users (e g, manufacturers) in multiple remote locations, and users may each have multiple components 150, 155. Data on operating characteristics from each of these components 150, 155 may be collected by their respective data acquisition systems 180 and sent to a centralized server or cloud server, as will be described in detail with reference to FIG. 5. The server may implement the predictive and other analytics system to create more accurate models to predict what types of measured operating characteristics correlate with system fault and other events, which allows the system to create alerts or recommendations on when to perform preventative maintenance.

Over time, the amount of data collected and analyzed about a particular type of component in a particular application may become so robust that the predictive and other analytics become more and more accurate to a desired degree of confidence; that is, the system may calculate a numerical probability of greater than a particular threshold (e.g., 95%) that a system fault event will occur within a certain predefined time period (e.g. 12 hours). In such cases, it is contemplated that components for these applications may be used by the data acquisition system with only a local computing device, rather than send the data to a remote server.

The data acquisition system and local computing device may be equipped with various algorithms, derived from the large data-gathering system implemented with multiple remote users. These algorithms may then be used to provide event alerts and information, preventative maintenance alerts to a local user without the local system being connected to a remote server.

Though highly accurate models may be derived from analyzing big data sets of operating characteristics for a particular type of component for a particular application, there are many different kinds of components 150, 155, and they are used for many different applications. Some component operating characteristics (i.e., temperature, impedance, voltage) may have extremely high variability from one unit to another. For example, temperature ranges between different units of the same model may be several degrees different (e.g., 5-10 degrees Celsius) depending on manufacturing differences or operating environments.

The number of differences between components 150, 155 and the number of different applications for which they may be used create an exponential number of event types, thresholds, and optimized preventative maintenance schedules. It is likely that each combination of type of component and application has its own preventative maintenance schedule that would maximize the time between events, thresholds, etc. while preventing any system fault events.

The system of the present disclosure provides ways to collect and record data from any combination of components 150, 155 and applications, analyze it over time, create models of operating characteristics based on the analysis, and implement machine learning to create algorithms that optimize the identification, characteristic, and information about events, such as arcs. A benefit of implementing machine learning to create algorithms is eliminating the need to manually create algorithms for each component and application combination.

As an example of how a machine learning algorithm may create event types and characteristics may include a “reinforcement”-type learning algorithm may take all the collected data about operating characteristics plus one input from an end user. The algorithm may correlate the rest of the collected data with the input from the user, it can automatically arrive at the operating characteristics that indicate a particular type of event has occurred.

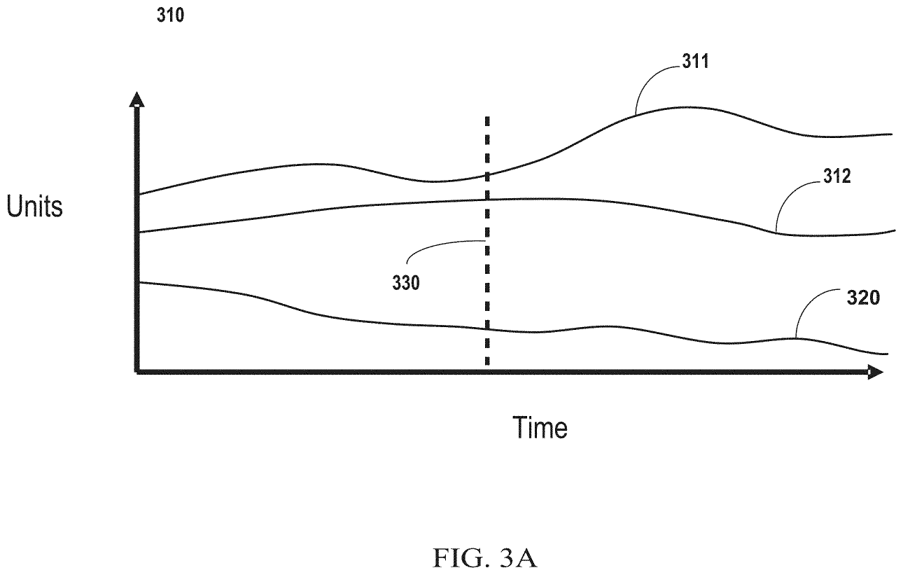

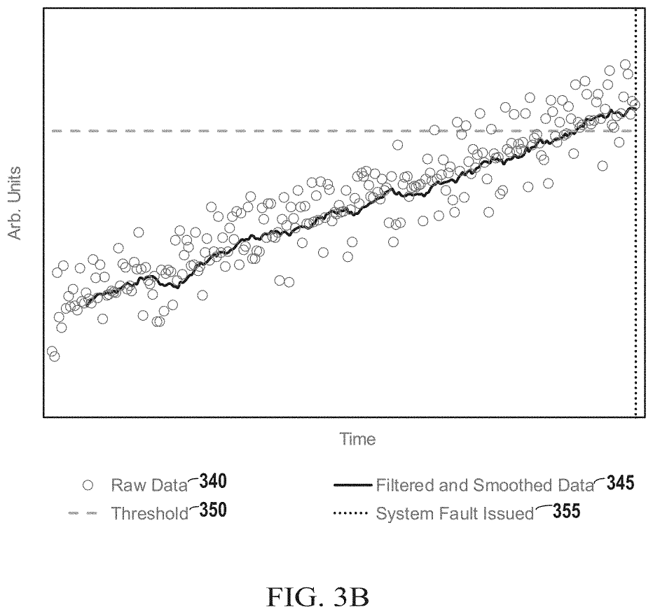

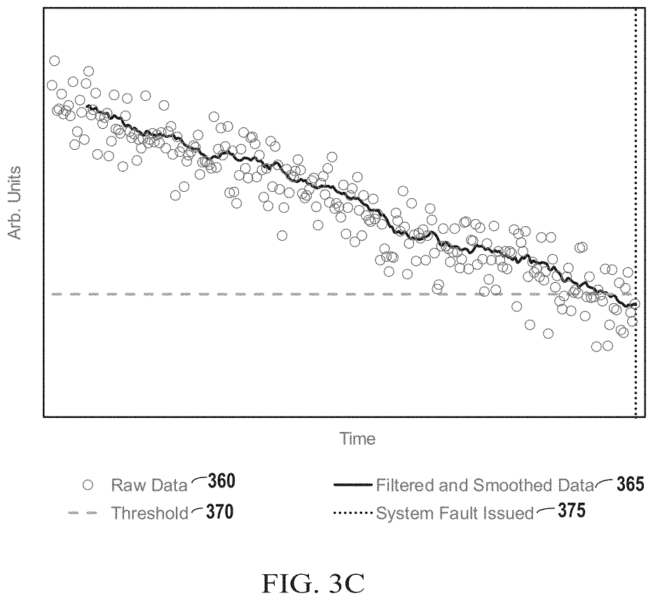

FIG. 3A depicts data that may be collected from a component (such as components 150, 155) and reported by an associated data acquisition system over time. Graph 310 shows measurements of N different parameters over time. These parameters may include DC voltage and current, AC voltage, current and phase, air flows and temperatures, water flows, temperatures and directions, relative degree of inductive and capacitive coupling, and other parameters or information.

Graph 310 shows Parameter-1, 311, Parameter-2, 312, and Parameter-N, 320, each varying over time. A particular “operating point” 330 represents the value of each of the operating parameters at a particular point in time. As shown, the various parameters may give measurements that vary independently of each other, and which do not visually convey any particular kind of correlation at the operating point 330. These parameters may be simply raw measured data, or they may be subjected to filtering and processing for the purpose of smoothing and removing artifacts. These parameters may also include estimates of indirect variables.

FIGS. 3B and 3C show examples in which particular parameters, which may be subsets of all the measured and calculated parameters for a particular component, increase (FIG. 3B) and decrease (FIG. 3C) in value over time. The raw data points 340, 360 represent actual measured or calculated data points, and the filtered and smoothed data lines 345, 365 show values with various faulty or anomalous readings eliminated. Each of the graphs depict a system fault event 355, 375 near the end of the measured time period, as well as a threshold line 350, 370 set to a value at which multiple data point measurements indicate that a system fault event is impending. It is contemplated that increasing measures in FIG. 3B and decreasing measures in FIG. 3C may be detected in the same component for the same application; that is, they could represent any of parameters 1-N in FIG. 3A. The predictive analytics system of the present disclosure may detect correlations and create models from data comprising measurements and system fault events as shown in FIGS. 3B. and 3C.

Many types of measures of operating characteristics require filtering of raw measured data because some of the raw measurements are due to false indicators. For example, when component or process turns on and off, several measurements may give temporary signals that are extremely high or extremely low, but these may not reflect actual conditions since they are artifacts of the transition between on and off states.

However, because the predictive data analytics system receives multiple pieces of data that correspond to the same time period or segment before the system fault event, it can identify correlations between data that deviates greatly from its normal trajectory and data that does not. It can identify thresholds that might otherwise not appear to be indicative of an event.

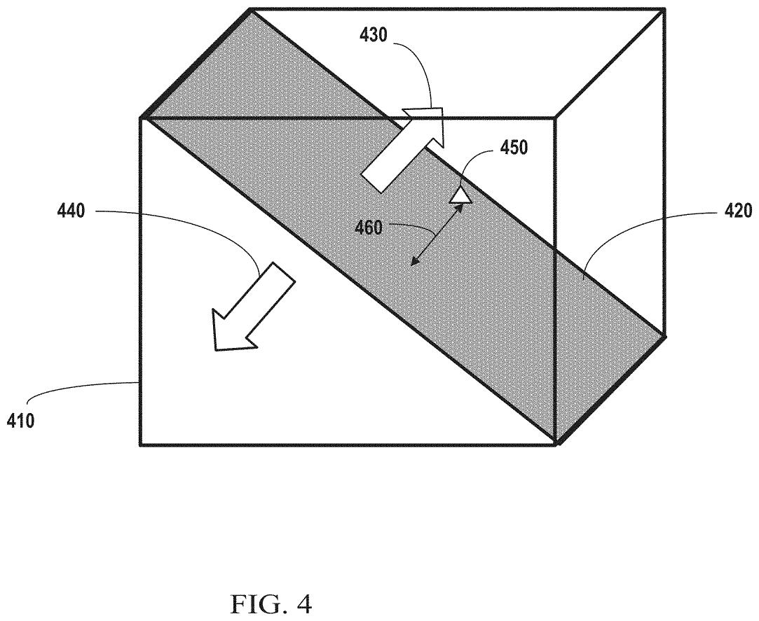

Turning to FIG. 4, an algorithm in the predictive analytics system may show that points in the N-dimensional space 410 within a certain distance from a hyperplane 420 are the most highly correlated with an impending or occurring event, and predict the need with a particular degree of confidence within a defined future period of time that an event will, or has occurred. The N-dimensional space 410 comprises component data which may be used to assess the health of the component, as well as events. These data may be processed for the purposes of smoothing, fitting, removing noise, and removing artifacts. As such events get recorded over time, the correlations between data may become more distinct, indicating the maximum instances of error rates that can occur before a system fault event occurs.

The N-dimensional space identified by the arrow 430 (also referred to as space 430), graphically depicted “above” the hyperplane 420, represents a space in which an operating point is satisfactory, and no event has, or is about to occur. The N-dimensional space identified by the arrow 440 (also referred to as space 440), graphically depicted “below” the hyperplane 420, represents a space in which an operating point is not satisfactory, or an event has occurred. At operating points within space 440, the component or system may require attention. A particular operating point 450 is shown in space 430. This particular operating point 450 may be the same as operating point 330 in FIG. 3A, representing measurements of N parameters at a particular point in time. Operating point 450 is shown at a distance 460 from the hyperplane 420. This distance 460 may be used to set or define a threshold. Based on an algorithmic determination correlating maximum instances of error rates that can occur before a system fault occurs, a user, or the predictive analytics system itself, may set a threshold that alerts for defining and detecting a fault the first time the distance from the operating point drops inside threshold. When a threshold is crossed an alert may be given, and action may be initiated.

In the graph in FIG. 3A, it is difficult to assess exactly which pieces of data, of those illustrated, indicate the occurrence of an event most strongly, because correlations are not visually apparent. When even more data points are collected, as they are in many embodiments, it quickly becomes impossible for a human analyst to assess which pieces of data correlate. The algorithms created by the predictive analytics system allow virtually every measurable characteristic to be assessed and correlated to system fault events. As a result, the thresholds for event alerts may be set at the most optimized level based on the most accurate data. In FIG. 4, it is possible that the threshold (i.e., the maximum distance from the hyperplane) may be set aggressively to not identify events. The more operating characteristics can be collected, the more calculations may be performed by the analytics system. Maximum optimization, however, may be achieved not only by taking in maximum different types of data, but also by taking it in repeatedly over the time domain.

FIG. 5 is an exemplary network architecture diagram showing how an analytics system 500 of the present disclosure may be implemented. Several individual components 501, 511, 521 are shown and labeled as “Type 1, Mfr. (manufacturer) A,” “Type 2, Mfr. A,” and “Type 3, Mfr. A,” respectively, to illustrate that the analytics system of the present disclosure may be implemented with different models of components made by the same manufacturer. Additional components 531 and 541 are labeled “Type 4, Mfr. B,” and “Type N, Mfr. N,” respectively, to illustrate that the same predictive analytics system may be implemented with any component from any manufacturer. Predictive analytics components, which, among other things, implement the algorithms to create event identifications and characteristics, are shown as “remote” analytics component 505 and “local” analytics component 515. The remote analytics component 505 may be implemented on one or more remote computing devices 190 and the local analytics component 515 may be implemented on one or more of the computing devices 185, which may reside in close proximity to the collection of data acquisition devices 555. Integration with either the remote analytics components 505 or local analytics components 515 are implemented through one or more data acquisition devices 502, 512, 522, 532, and 542. Although each component 501, 511, 521, 531, 541 is depicted as connected to one data acquisition device 502, 512, 522, 532, 542, in embodiments, more than one component may be connected to a single data acquisition device.

The remote analytics component 505 may be remote in the sense that it is located at a robust server and takes in data from multiple components. But a remote analytics component 505 may in fact be deployed “on-premise,” e.g., at a semiconductor manufacturing plant which uses multiple components. The remote analytics component 505 may be on a LAN in such cases. In other embodiments, it may be at a remote cloud server on the internet, which may receive data from components in many remote geographical locations, such as different manufacturing facility buildings, or different cities, states, and countries.

The local analytics component 515, in contrast, may be run on a local PC or server (e.g., on one or more computing devices 185), and may implement the analytics algorithm and event warnings for one or just a few of the components 501, 511, 521, 531, 541. It is contemplated that a local analytics component 515 may be implemented in an external computing device, or a computing device integrated with the data acquisition device, such as one uniquely designed with an interface, processor, and memory compatible with the data acquisition device.

Each of the data acquisition devices 502, 512, 522, 532, and 542 may implement a particular protocol that defines what data is collected and/or measured from its associated component 501, 511, 521, 531, 541. Different ones of the components 501, 511, 521, 531, 541 may be equipped with different sensors and be otherwise configured differently from others, which may dictate the type of data that is possible to be measured. The different protocols 503, 513, 523, 533, 543 may themselves be changed according to different applications being run by their associated components. That is, Type 1 Protocol 503 may have different iterations such as protocol “1A,” “1B,” “1C,” etc.

Once data is acquired by the data acquisition device under a particular protocol, the data may be transmitted to either a local database 550, a remote database 570, or both. Data acquisition devices 502, 512, 522, 532, and 542 are shown grouped and logically connected as the collection of data acquisition devices 555 to remote database 570 to illustrate that data may be transmitted by each of these individual units to the remote database 570. Each individual one of the data acquisition devices 502, 512, 522, 532, and 542 may be in a different geographical location. The data, acquired via different protocols, may be integrated or assimilated through a unified protocol 548, which systematizes different types of acquired data so that it may be processed in a uniform manner in the databases 550, 570.

Referring to the remote analytics component 505, it is contemplated that the database 570 may comprise many large data sets acquired and stored over time. These are depicted as big data component 572 and represents the voluminous raw data that may be analyzed to reveal patterns and used to implement the other aspects of the predictive analytics component. This big data component 572 may be organized and managed through the database/data management component 571, which may be implemented through commercially available tools, including relational database management systems such as SQL.

The remote database 570 is configured to serve data to the analytics engine 580. The analytics engine 580 may be executed (e.g., as processor-executable instructions) on a server and may comprise several applications. These applications may include a data science component 584 and a data engineering component 585. Each of these may comprise tools and interfaces for data scientists and data engineers to manipulate data, provide inputs such as thresholds, and assist in creating algorithms. The analytics engine 580 may also comprise an applications development component 581, which may create specific algorithms for particular components and applications. Once developed, the algorithms for the specific applications may be deployed with the local analytics component 515 or even the individual components that are to be used for those applications. Those deployed components may run independently and not require connection to a local or remote analytics component, having local algorithms implemented directly within the component.

In embodiments, the local analytics component 515 may not be within one or more of the components 501, 511, 521, 531, and 541, but the components 501, 511, 521, 531, and 541 and connected local analytics component 515 may run independently, without any connection to the remote analytics component 505. The model development component 582 may create models of likelihoods of events occurring with mathematical probabilities with certain periods of time based on analysis of the big data 572. It is contemplated that the applications development component 581 and the model development component 582 may be implemented through machine learning programs.

Because of the large data sets that may be used to create the applications and models, data visualization is beneficial for providing usable insights to users such as data scientists and data engineers. The analytics engine 580 may therefore comprise a big data visualization component 583, which may be implemented as a graphical user interface with graphs, charts, and other visualization tools.

The local analytics engine 560 may comprise many similar components and functions as the remote predictive analytics engine 580, but may be implemented on a smaller scale and designed for an end user of the one or more attached component(s) 501, 511, 521, 531, and 541. As shown, an applications configuration component 561 of a local analytics engine 560 may use the data collected in local database 550 to create, detect, and/or identify events for the connected component(s) 501, 511, 521, 531, and 541. The applications configuration component 561 may be used to implement operations initially created on the local analytics component 515, and may be used to adjust local configurations and set local thresholds. The local data visualization component 562 may show the user the actual alerts 563, analytics 564, analyzed information, and/or KPI (key performance indicators) 565 (e.g., on a graphical user interface).

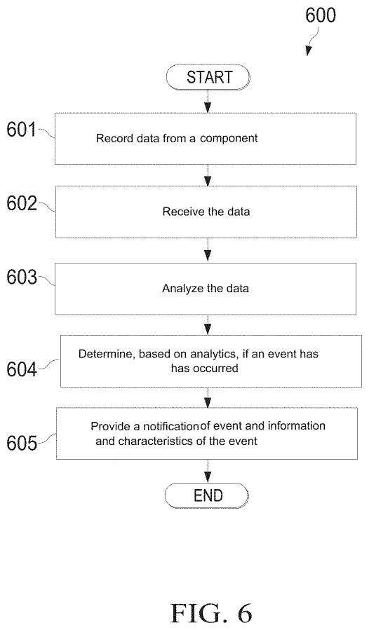

FIG. 6 is a flowchart depicting a method 600 that may be performed to implement embodiments of the disclosure. Method steps can be interchanged without departing from the scope of the invention. The method may first comprise, at step 601 recording data from a component (e.g., from an RF power supply, DC power supply, match network, etc.). The data may comprise measurements of one or more operating characteristics of the component over a period of time and/or a plurality of indications of system fault event. The method may then comprise, at step 602, receiving the data, and at step 603, analyzing the data. The method may comprise, at step 604, determining, based on analyzing algorithms, and/or correlations between the measurements of the one or more operating characteristics and/or the plurality of system fault events, a threshold of an operating point or a definition and identification of an event. The operating point may comprise the measurements of the one or more operating characteristics at a particular time. The threshold may signify a pending or occurrence of a system fault event to a defined degree of confidence within a specified window of time. The method may then comprise, at step 605, providing a notification to the user. The notification to the user may include information which allows the user to know the time, segment, and other information so that the user has an indication of where to look for defects, severity of the defects, and whether or not to scrap the material affected by the event.

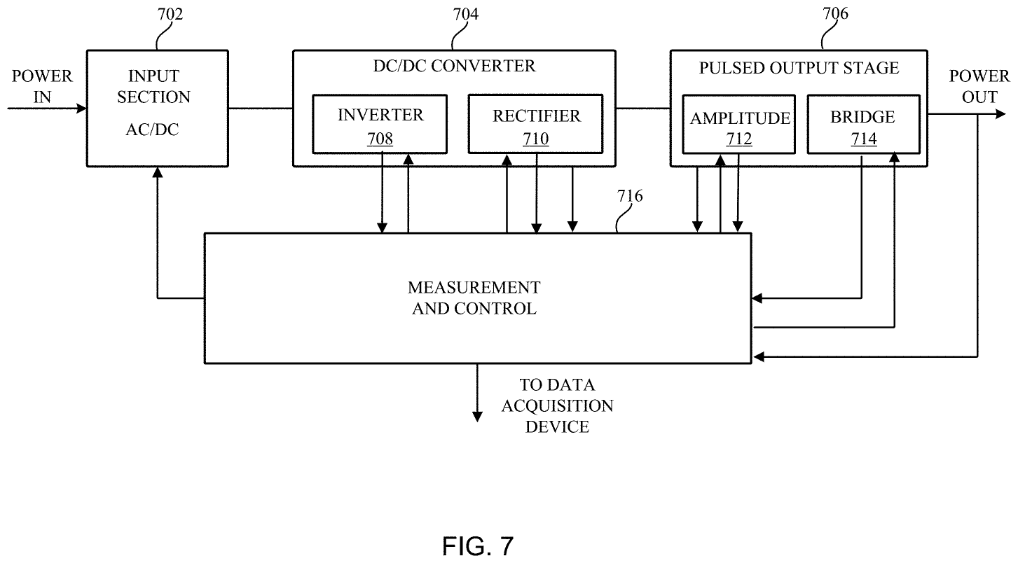

Referring next to FIG. 7, shown is a block diagram depicting a power supply, which is an example of a type of device that may be used to realize one or more of the components 150, 155, 501, 511, 521, 531, 541. As shown, the pulsed-DC power supply may functionally be characterized in terms of an input section 702, a DC/DC converter 704 and a pulsed output stage 706. The input section 702 may include relay switches and rectification components (not shown), the DC/DC converter 704 may include one or more inverters 708 and rectifiers 710, and the pulsed output stage 706 may include one or more an amplitude control components 712 and bridge circuits 714, which are shown coupled to a measurement and control module 716. The depiction of components of the pulsed-DC power supply is intended to show examples of the types of subcomponents that may be monitored and controlled. In one application, the power applied by the pulsed-DC power supply may be applied to an electrode (e.g., a magnetron) of a plasma processing chamber to provide a bipolar waveform to the electrode (so the electrode alternates as a cathode and an electrode). And the depicted power-processing chain may be duplicated to provide multiple power outputs (e.g., to multiple electrodes).

As shown, operating characteristics (e.g., voltage, current, temperature) may be obtained from within multiple subcomponents such as the input section 702, DC/DC converter 704, and the pulsed output stage 706. These operating characteristics may be obtained and used to characterize the pulsed-DC supply in connection with a variety of events such as ignition, arc events, and fault events (e.g., overvoltage events). As discussed above with reference to FIGS. 3A-3C, and further herein below, the operating characteristics may be measured and captured over time in the form of parameter values and modeled in connection with one or more events. And in operation, the operating characteristics may be used to access the model to predict events and/or troubleshoot and address issues.

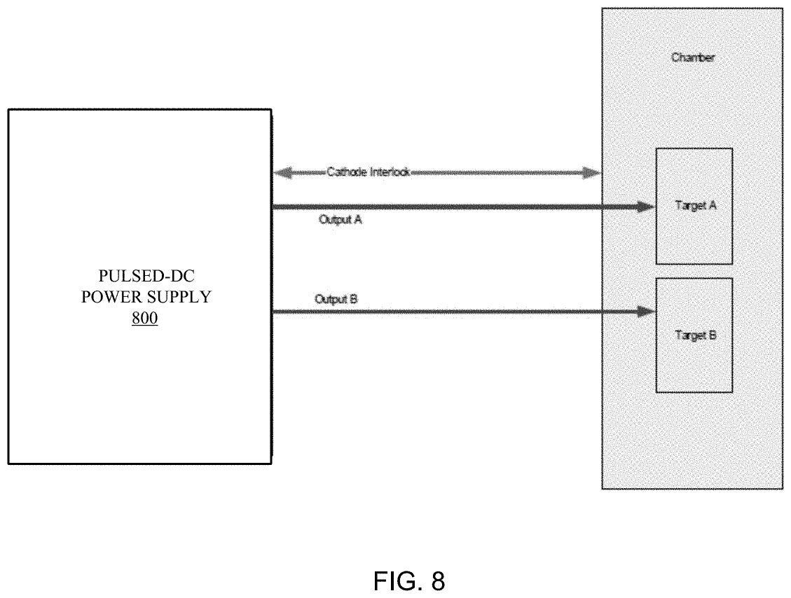

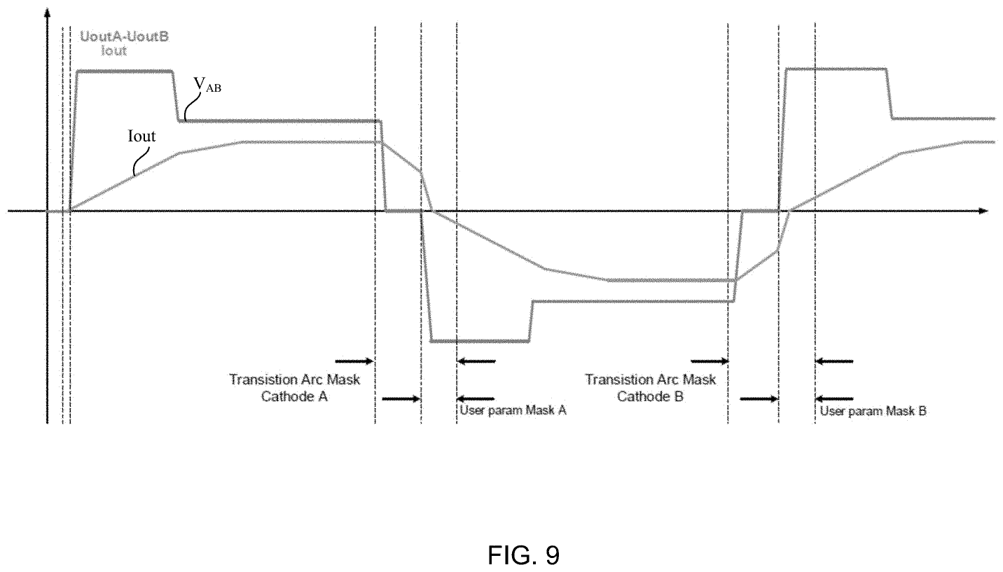

FIG. 8 depicts a pulsed-DC power supply 800 that may be realized by duplicating aspects of the power-processing chains depicted in FIG. 7. As shown, the pulsed-DC power supply comprises two outputs coupled to two targets (target A and target B) where each target is an electrode that is coupled to target material. As shown in FIG. 9, the potential difference, V_{AB}, at target A relative to target B may be a bipolar voltage waveform that alternates between positive and negative so that target A operates as a cathode while target B is operating as an anode (during one half of a voltage cycle), and target A operates as an anode while target B operates as a cathode (during another half of the voltage cycle).

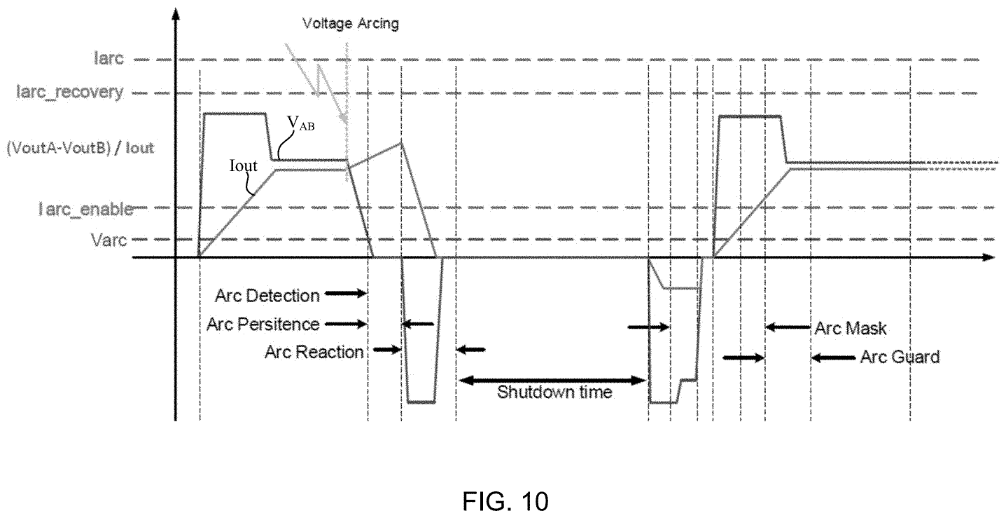

In operation of the pulsed-DC power supply 800, differential arcs between targets may occur and arcs-to-ground may occur between a target and ground. As shown in FIG. 10, there may be several thresholds that may trigger arc management operations of the pulsed-DC power supply 800. For example, when V_{AB}<Varc, where Varc is a differential arc threshold, the pulsed-DC power supply may alter or disconnect power from its outputs. But in addition, one or more of the measured operating characteristics may reach a level to trigger a corresponding data acquisition device to capture operating characteristics so the operating conditions may be stored. In an alternative mode of operation, a data acquisition device may capture operating characteristics in a “free run” mode of operation in which operating characteristics data is captured every n seconds where n may be configurable. As discussed above with reference to FIGS. 2A and 2B, low resolution data may be captured and segmented during typical modes of operation and when an event is detected (e.g., an arc event) high resolution data may be captured.

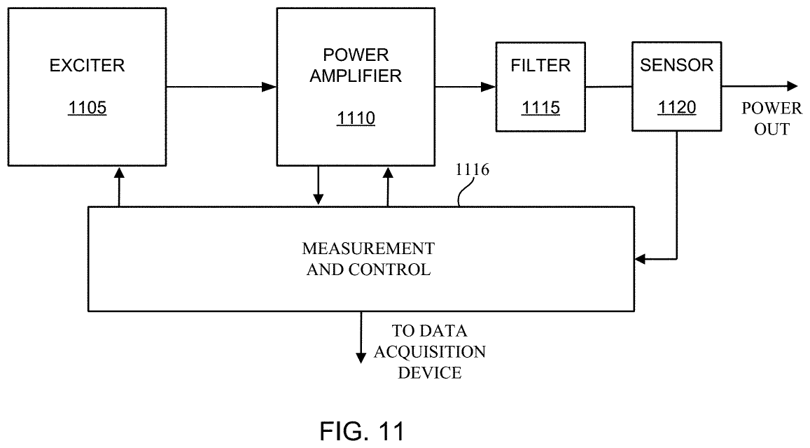

Referring next to FIG. 11 shown is a block diagram of an RF generator as another example of the component 150 that may be utilized in the system 100. As shown, the RF generator includes exciter 1105, power amplifier 1110, filter 1115, and a sensor 1120. The exciter 1105 generates an oscillating signal at RF frequencies, typically in the form of a square wave. Power amplifier 1110 amplifies the signal produced by exciter 1105 to produce an amplified oscillating signal. For example, in one embodiment power amplifier 1110 amplifies an exciter output signal of 1 mW to 3 kW. Filter 1115 filters the amplified oscillating signal to produce a signal composed of a single RF frequency (a sinusoid).

Sensor 1120 measures one or more properties of the plasma load in plasma processing chamber 120. In one embodiment, sensor 1120 obtains a measure of impedance Z of the plasma load. Depending on the particular embodiment, sensor 1120 can be, for example and without limitation, a VI sensor or a directional coupler. Such impedance can alternatively be expressed as a complex reflection coefficient, which is often denoted as “F” (gamma) by those skilled in the art. As shown, a measurement and control module 1116 may capture operating characteristics (e.g., voltage, current, impedance, temperature) of the RF generator for modeling the RF generator in connection with various events (e.g., instabilities). And once modeled, events may be predicted and preempted.

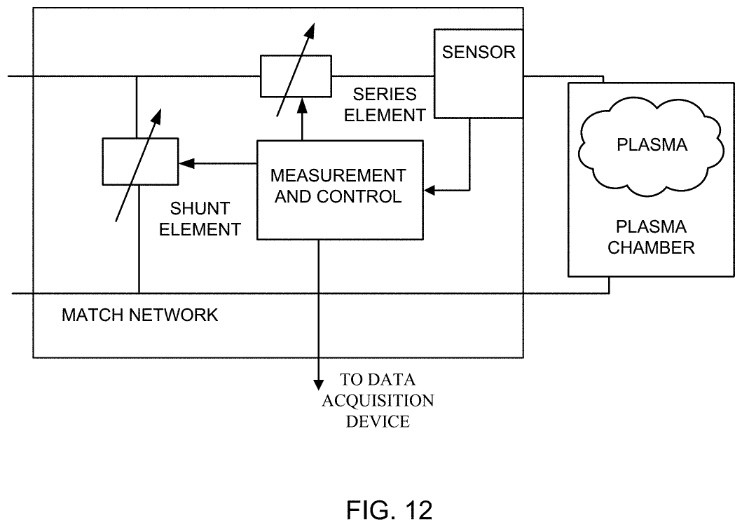

Referring to FIG. 12, shown is a simplified representation of a match network as yet another example of the component 150 that may be used in the system 100. As shown, the match network may comprise a shunt element disposed across transmission lines of the match network and a series element disposed in series along one of the transmission lines. Each of the shunt element and the series element may be coupled to a controller by control lines to enable the controller to adjust each of the series element and the shunt element. Each of the shunt element and the series element may be realized by one or more reactive elements. The reactive elements, for example, may be variable capacitors, which may be realized by variable vacuum capacitors or a plurality of switched capacitors (that provide a selectable capacitance that can be varied). More specifically, each of the shunt element and the series element may include a variable vacuum capacitor and/or a plurality of switched capacitors.

As shown, a measurement and control module may provide setting information about the shunt and series elements to a corresponding data acquisition device along with operating characteristics data such as voltage, current, phase, and/or impedance information. The captured data may be used to model the match network in connection with a variety of events (e.g., capacitor failure), and the model may be used to predict and preempt undesirable events.

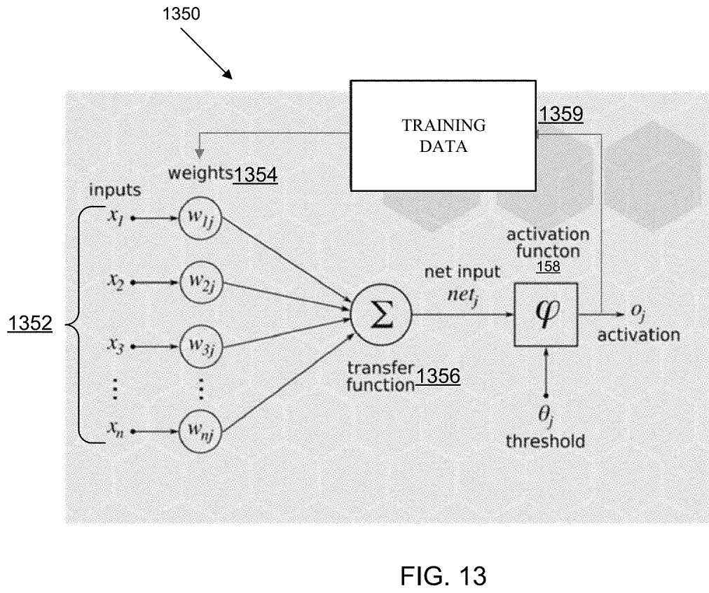

As discussed above, the model development component 582 may be implemented through machine learning programs. In some implementations, the model development component 582 may execute an artificial neural network (ANN). Referring to FIG. 13, shown is an example of a neural network 1250 that may be used to produce a model of the system components 150, 155, 501, 511, 521, 531, 541. As discussed further herein, the resultant model(s) may be used to anticipate faults, troubleshoot aspects of the components 150, 155, 501, 511, 521, 531, 541, and/or adjust operational aspects of the components 150, 155, 501, 511, 521, 531, 541.

The neural network 1350 may be initially trained in a controlled process to recognize patterns of the various operating characteristics 1305 that correspond to normal or acceptable operation of system 100, as well as to recognize patterns of operating characteristics 1205 that correspond to a fault condition or unacceptable operation of system 1300. In field operation, after the initial training, neural network 1350 continues to be trained by recognizing any new patterns of operational parameter values and, based on user feedback, either classifying those patterns as corresponding to acceptable operation or corresponding to a fault condition. In this way, neural network 1350 develops and refines its pattern-recognition accuracy over time.

In one embodiment, data representative of operating characteristics 1305 is streamed from one or more of the data acquisition devices 555 to the model development component 582, which uses the neural network 1350 to determine whether the operating characteristics are consistent with existing parameter values, and may modify the weighting of inputs to neural network 1350 when the incoming operating characteristics are inconsistent with the training parameter values. The analytics engine may then provide a report indicating how far out of normal range operational parameters such as voltages, current, temperature, capacitance, etc. are, or conversely, whether the incoming parameter values are within normal ranges. By use of neural network 1350, sophisticated and superimposed value changes can be detected and correlated with a unique or fault condition that may not ordinarily or easily be detected by a human operator.

The neural network also updates weights 1354 applied to the input operating characteristics based on inconsistencies with existing (e.g., trained) parameter values, and may also provide more general health reports on any weighted combination of operating characteristics or on the entire system 100. As shown, the neural network 1250 comprises inputs 1352 (x₁, x₂, x₃ . . . xₙ), weights 1354 (w₁ⱼ, w₂ⱼ, w₃ⱼ . . . wₙⱼ), transfer function 1356 (Σ), activation function 158 ( [symbol] ) and feedback training data 1359.

Inputs (x₁, x₂, x₃ . . . xₙ) correspond to the operating characteristics that provided to the analytics engine 580 from the data acquisition devices. For example, x₁ may be a temperature parameter value, x₂ may be a voltage parameter value x₃ may be a current parameter value, and so on. Weights (w₁ⱼ, w₂ⱼ, w₃ⱼ, . . . , wₙⱼ) correspond to weights or coefficients that are assigned to each input (x₁, x₂, x₃ . . . xₙ). Weights (w₁ⱼ, w₂ⱼ, w₃ⱼ, . . . , wₙⱼ) may be, for example, a value from −1 to +1. Weights (w₁ⱼ, w₂ⱼ, w₃ⱼ, . . . , wₙⱼ) are initially generated in training the model, and a bigger weight value may be assigned to more important inputs (x₁, x₂, x₃ . . . xₙ). These weights may be modified on an ongoing basis when any input operating characteristics are inconsistent with existing parameter values. In addition, weights may be adjustable based on user feedback. For example, if a user reports a fault condition or anomaly based on some operating characteristic or combination of operating characteristics, that operatic characteristic (combination of operating characteristics) may be assigned a higher weight. Weights may be incremented or decremented over time based on the learned importance of the input parameters associated with those weights.

Each input (x₁, x₂, x₃ . . . xₙ) is multiplied by each weight (w₁ⱼ, w₂ⱼ, w₃ⱼ . . . wₙⱼ). This controls the significance and impact of each input, and the weighted inputs are then summed at the transfer function 156 (Σ). Thus, Σweight₁·input₁=weight₁·input₁+weight₂·input₂+weight₃·input₃ . . . +weightₙ·inputₙ. The summed weights impact how significant total changes are, controlling the level of reaction of the system. The summed weighted input value is dynamic and may be continuously and automatically modified based on inconsistencies between operating characteristics and existing parameter values.

Activation function 158 ( [symbol] ) applies a threshold or bias Θⱼ to the summed weighted inputs (net input netⱼ), and an activation function is applied to generate an activation output oⱼ that is a number between zero and one. In one implementation, the activation function is a sigmoid activation function. Sigmoid activation function 158 may be S(x)=1/(1+e^{-x})=e^{x}/(e^{x}+1), where x is a dot product of a transposed matrix. As those of ordinary skill in the art will appreciate, the sigmoid activation function is depicted by a characteristic “S”-shaped curve, and can map any value to a value from 0 to 1 to assist in normalizing the weighted sum of the inputs netⱼ. Mathematically, the model may be trained by applying the dx/dt chain rule and sigmoid function to normalize the output to one or zero. This is repeated in a loop (feedback training data 1359) from one time to millions of times to converge the error in a fault state to as close to zero as possible, or to converge in a normal state to as close to one as possible. Thus, in this manner, based on a dynamic weighted combination of operating characteristics 1305, the neural network 1350 may enable the analytics engine 580 to provide an indication of the general health of system 100, and is able to predict and react to fault or other unique conditions as they arise.

In some implementations, the machine learning may autonomously generate one or more thresholds. Multiple iterations of testing, for example, may produce the threshold line 350, 370 at a value at which multiple data point measurements indicate that a system event is impending. It is contemplated that ongoing machine learning with ongoing increasing measures (described with reference to FIG. 3B and decreasing measures described with reference to FIG. 3C) may be detected in the same component for the same application; that is, they could represent any of parameters 1-N in FIG. 3A. The predictive analytics system of the present disclosure may detect correlations and create models from data comprising measurements and system fault events as shown in FIGS. 3B. and 3C. Examples of parameters (e.g., voltage, current, and temporal aspects of the same) associated with an arc event are described with reference to FIGS. 2B and 10.

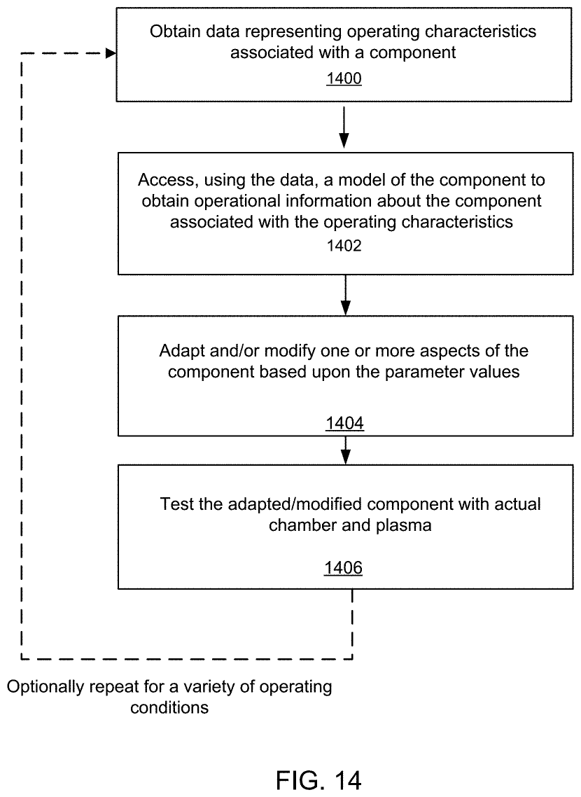

Once produced, the resultant model(s) may be used to troubleshoot issues that may arise during plasma processing. Referring to FIG. 14 for example, shown is a flowchart depicting a method for troubleshooting issues and adapting/modifying one or more of the components 150, 155, 501, 511, 521, 531, 541 to address the issues. As shown, data is obtained that represents operating characteristics associated with a component (Block 1400). Using the data, a model of the component is accessed to obtain operational information about the component that is associated with the operating characteristics (Block 1402). With the information about the component, one or more aspects of the component may be adapted and/or modified (Block 1404). The adapted/modified component may then be tested with an actual chamber and plasma (Block 1406). This process (described with reference to Blocks 1400-1406) may optionally be repeated (e.g., to continue to improve operation of the component).

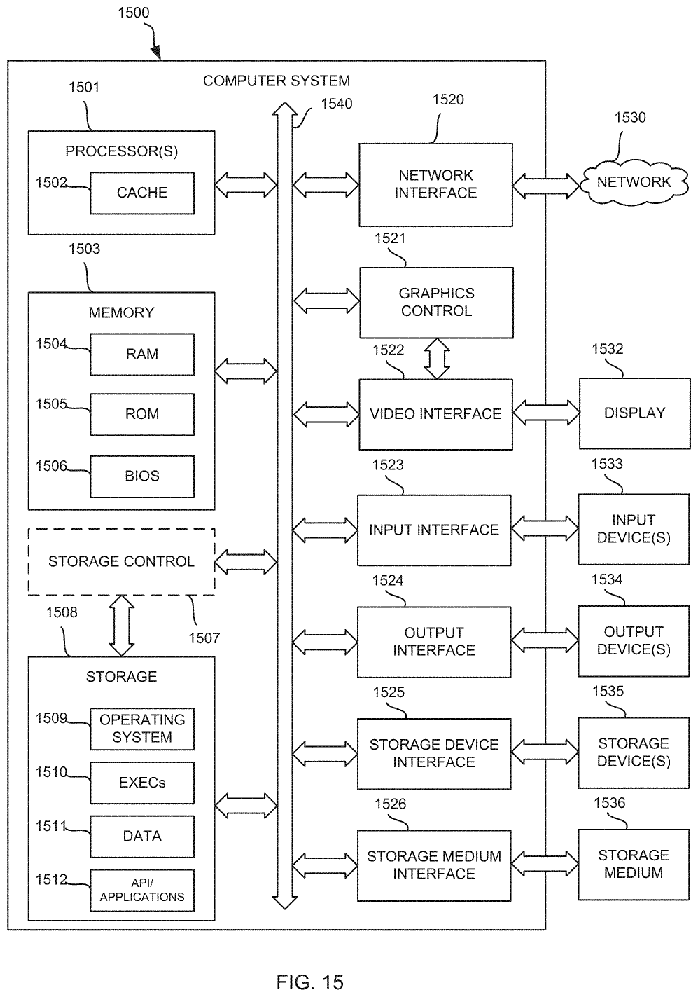

The systems and methods described herein can be implemented in a computer system in addition to the specific physical devices described herein. FIG. 15 shows a diagrammatic representation of one embodiment of a computer system 1500 within which a set of instructions can execute for causing a device to perform or execute any one or more of the aspects and/or methodologies of the present disclosure. Local analytics engine 560 and remote analytics engine 580 in FIG. 5 are two applications of the computer system 1500. The components in FIG. 15 are examples only and do not limit the scope of use or functionality of any hardware, software, firmware, embedded logic component, or a combination of two or more such components implementing particular embodiments of this disclosure. Some or all of the illustrated components can be part of the computer system 1500. For instance, the computer system 1500 can be a general purpose computer (e.g., a laptop computer) or an embedded logic device (e.g., an FPGA), to name just two non-limiting examples.

Computer system 1500 includes at least a processor 1501 such as a central processing unit (CPU), graphics processing unit (GPU) or an FPGA to name three non-limiting examples. The computer system 1500 may also comprise a memory 1503 and a storage 1508, both communicating with each other, and with other components, via a bus 1540. The bus 1540 may also link a display 1532, one or more input devices 1533 (which may, for example, include a keypad, a keyboard, a mouse, a stylus, etc.), one or more output devices 1534, one or more storage devices 1535, and various non-transitory, tangible computer-readable storage media 1536 with each other and with one or more of the processor 1501, the memory 1503, and the storage 1508. All of these elements may interface directly or via one or more interfaces or adaptors to the bus 1540. For instance, the various non-transitory, tangible computer-readable storage media 1536 can interface with the bus 1540 via storage medium interface 1526. Computer system 1500 may have any suitable physical form, including but not limited to one or more integrated circuits (ICs), printed circuit boards (PCBs), mobile handheld devices (such as mobile telephones or PDAs), laptop or notebook computers, distributed computer systems, computing grids, or servers.

Processor(s) 1501 (or central processing unit(s) (CPU(s))) optionally contains a cache memory unit 1502 for temporary local storage of instructions, data, or computer addresses. Processor(s) 1501 are configured to assist in execution of computer-readable instructions stored on at least one non-transitory, tangible computer-readable storage medium. Processor(s) 1501 may include one or more graphics processing units (GPU(s)). In some embodiments, the GPU may be used to execute machine learning AI (artificial intelligence) programs. Computer system 1500 may provide functionality as a result of the processor(s) 1501 executing software embodied in one or more non-transitory, tangible computer-readable storage media, such as memory 1503, storage 1508, storage devices 1535, and/or storage media 1536 (e.g., read only memory (ROM)). For instance, the method 600 in FIG. 6 may be embodied in one or more non-transitory, tangible computer-readable storage media. The non-transitory, tangible computer-readable storage media may store software that implements particular embodiments, such as the method 600 and processor(s) 1501 may execute the software. Memory 1503 may read the software from one or more other non-transitory, tangible computer-readable storage media (such as mass storage device(s) 1535, 1536) or from one or more other sources through a suitable interface, such as network interface 1520. The software may cause processor(s) 1501 to carry out one or more processes or one or more steps of one or more processes described or illustrated herein. Carrying out such processes or steps may include defining data structures stored in memory 1503 and modifying the data structures as directed by the software. In some embodiments, an FPGA can store instructions for carrying out functionality as described in this disclosure (e.g., the method 600). In other embodiments, firmware includes instructions for carrying out functionality as described in this disclosure (e.g., the method 600)

The memory 1503 may include various components (e.g., non-transitory, tangible computer-readable storage media) including, but not limited to, a random access memory component (e.g., RAM 1504) (e.g., a static RAM “SRAM”, a dynamic RAM “DRAM, etc.), a read-only component (e.g., ROM 1505), and any combinations thereof. ROM 1505 may act to communicate data and instructions unidirectionally to processor(s) 1501, and RAM 1504 may act to communicate data and instructions bidirectionally with processor(s) 1501. ROM 1505 and RAM 1504 may include any suitable non-transitory, tangible computer-readable storage media described below. In some instances, ROM 1505 and RAM 1504 include non-transitory, tangible computer-readable storage media for carrying out the method 600. In one example, a basic input/output system 1506 (BIOS), including basic routines that help to transfer information between elements within computer system 1500, such as during start-up, may be stored in the memory 1503.

Fixed storage 1508 is connected bidirectionally to processor(s) 1501, optionally through storage control unit 1507. Fixed storage 1508 provides additional data storage capacity and may also include any suitable non-transitory, tangible computer-readable media described herein. Storage 1508 may be used to store operating system 1509, EXECs 1510 (executables), data 1511, API applications 1512 (application programs), and the like. For instance, the storage 1508 could be implemented for storage of data as described in FIG. 5. Often, although not always, storage 1508 is a secondary storage medium (such as a hard disk) that is slower than primary storage (e.g., memory 1503). Storage 1508 can also include an optical disk drive, a solid-state memory device (e.g., flash-based systems), or a combination of any of the above. Information in storage 1508 may, in appropriate cases, be incorporated as virtual memory in memory 1503.

In one example, storage device(s) 1535 may be removably interfaced with computer system 1500 (e.g., via an external port connector (not shown)) via a storage device interface 1525. Particularly, storage device(s) 1535 and an associated machine-readable medium may provide nonvolatile and/or volatile storage of machine-readable instructions, data structures, program modules, and/or other data for the computer system 1500. In one example, software may reside, completely or partially, within a machine-readable medium on storage device(s) 1535. In another example, software may reside, completely or partially, within processor(s) 1501.

Bus 1540 connects a wide variety of subsystems. Herein, reference to a bus may encompass one or more digital signal lines serving a common function, where appropriate. Bus 1540 may be any of several types of bus structures including, but not limited to, a memory bus, a memory controller, a peripheral bus, a local bus, and any combinations thereof, using any of a variety of bus architectures. As an example and not by way of limitation, such architectures include an Industry Standard Architecture (ISA) bus, an Enhanced ISA (EISA) bus, a Micro Channel Architecture (MCA) bus, a Video Electronics Standards Association local bus (VLB), a Peripheral Component Interconnect (PCI) bus, a PCI-Express (PCI-X) bus, an Accelerated Graphics Port (AGP) bus, HyperTransport (HTX) bus, serial advanced technology attachment (SATA) bus, and any combinations thereof.

Computer system 1500 may also include an input device 1533. In one example, a user of computer system 1500 may enter commands and/or other information into computer system 1500 via input device(s) 1533. Examples of an input device(s) 1533 include, but are not limited to, an alpha-numeric input device (e.g., a keyboard), a pointing device (e.g., a mouse or touchpad), a touchpad, a joystick, a gamepad, an audio input device (e.g., a microphone, a voice response system, etc.), an optical scanner, a video or still image capture device (e.g., a camera), and any combinations thereof. Input device(s) 1533 may be interfaced to bus 1540 via any of a variety of input interfaces 1523 (e.g., input interface 1523) including, but not limited to, serial, parallel, game port, USB, FIREWIRE, THUNDERBOLT, or any combination of the above.

In particular embodiments, when computer system 1500 is connected to network 1530 computer system 1500 may communicate with other devices, such as mobile devices and enterprise systems, connected to network 1530. Communications to and from computer system 1500 may be sent through network interface 1520. For example, network interface 1520 may receive incoming communications (such as requests or responses from other devices) in the form of one or more packets (such as Internet Protocol (IP) packets) from network 1530, and computer system 1500 may store the incoming communications in memory 1503 for processing. Computer system 1500 may similarly store outgoing communications (such as requests or responses to other devices) in the form of one or more packets in memory 1503 and communicated to network 1530 from network interface 1520. Processor(s) 1501 may access these communication packets stored in memory 1503 for processing.

Examples of the network interface 1520 include, but are not limited to, a network interface card, a modem, and any combination thereof. Examples of a network 1530 or include, but are not limited to, a wide area network (WAN) (e.g., the Internet, an enterprise network), a local area network (LAN) (e.g., a network associated with an office, a building, a campus or other relatively small geographic space), a telephone network, a direct connection between two computing devices, and any combinations thereof. A network, such as network 1530, may employ a wired and/or a wireless mode of communication. In general, any network topology may be used.

Information and data can be displayed through a display 1532. Examples of a display 1532 include, but are not limited to, a liquid crystal display (LCD), an organic liquid crystal display (OLED), a cathode ray tube (CRT), a plasma display, and any combinations thereof. The display 1532 can interface to the processor(s) 1501, memory 1503, and fixed storage 1508, as well as other devices, such as input device(s) 1533, via the bus 1540. The display 1532 is linked to the bus 1540 via a video interface 1522, and transport of data between the display 1532 and the bus 1540 can be controlled via the graphics control 1521.

In addition to a display 1532, computer system 1500 may include one or more other peripheral output devices 1534 including, but not limited to, an audio speaker, a printer, and any combinations thereof. Such peripheral output devices may be connected to the bus 1540 via an output interface 1524. Examples of an output interface 1524 include, but are not limited to, a serial port, a parallel connection, a USB port, a FIREWIRE port, a THUNDERBOLT port, and any combinations thereof.

In addition, or as an alternative, computer system 1500 may provide functionality as a result of logic hardwired or otherwise embodied in a circuit, which may operate in place of or together with software to execute one or more processes or one or more steps of one or more processes described or illustrated herein. Reference to software in this disclosure may encompass logic, and reference to logic may encompass software. Moreover, reference to a non-transitory, tangible computer-readable medium may encompass a circuit (such as an IC) storing software for execution, a circuit embodying logic for execution, or both, where appropriate. The present disclosure encompasses any suitable combination of hardware, software, or both.

Those of skill in the art will understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Within this specification, the same reference characters are used to refer to terminals, signal lines, wires, etc. and their corresponding signals. In this regard, the terms “signal,” “wire,” “connection,” “terminal,” and “pin” may be used interchangeably, from time-to-time, within this specification. It also should be appreciated that the terms “signal,” “wire,” or the like can represent one or more signals, e.g., the conveyance of a single bit through a single wire or the conveyance of multiple parallel bits through multiple parallel wires. Further, each wire or signal may represent bi-directional communication between two, or more, components connected by a signal or wire, as the case may be.

Those of skill will further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein (e.g., the method 600) may be embodied directly in hardware, in a software module executed by a processor, a software module implemented as digital logic devices, or in a combination of these. A software module may reside in RAM memory, flash memory, ROM memory, EPROM memory, EEPROM memory, registers, hard disk, a removable disk, a CD-ROM, or any other form of non-transitory, tangible computer-readable storage medium known in the art. An exemplary non-transitory, tangible computer-readable storage medium is coupled to the processor such that the processor can read information from, and write information to, the non-transitory, tangible computer-readable storage medium. In the alternative, the non-transitory, tangible computer-readable storage medium may be integral to the processor. The processor and the non-transitory, tangible computer-readable storage medium may reside in an ASIC. The ASIC may reside in a user terminal. In the alternative, the processor and the non-transitory, tangible computer-readable storage medium may reside as discrete components in a user terminal. In some embodiments, a software module may be implemented as digital logic components such as those in an FPGA once programmed with the software module.

The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A system for defining, detecting or characterizing and event in a plasma processing system, comprising:
a component,
a data acquisition device operatively coupled to the component and configured to record data from the component, the data comprising:
measurements of one or more operating characteristics of the component over a period of time; and
a plurality of indications of system fault events;
a computing device configured to:
receive the data from the data acquisition device;
analyze the data;
determine, based on correlations between the measurements of the one or more operating characteristics and the system fault events, a threshold of an operating point, the operating point comprising:
the measurements of the one or more operating characteristics at a particular time;
wherein the threshold signifies a pending system fault event is probable to a defined degree of confidence within a specified window of time; and
provide a notification to perform preventative maintenance on the component.

2. The system of claim 1, wherein the one or more operating characteristics comprise one or more of:
a current;
a voltage;
a temperature; and
an impedance.

3. The system of claim 1, wherein the component comprises a power source, power supply, match network, and/or a generator, and/or combinations thereof.

4. The system of claim 1, further comprising:
a plurality of additional components; and
a plurality of additional data acquisition devices, and wherein
the data further comprises:
additional measurements from each of the plurality of additional components; and
additional indications of system faults from each of the component and the additional components.

5. The system of claim 4, wherein at least some of the plurality of additional components are in different geographical locations.

6. The system of claim 1, wherein the determining is implemented by a machine learning program.

7. The system of claim 6, wherein the machine learning program automatically develops an algorithm to set the threshold.

8. The system of claim 6, wherein the machine learning program receives input from a user to assist in the determining.

9. The system of claim 1, wherein the computing device is a remote server; and wherein:
an algorithm for event definition, detection, and characterization is created at the remote server for a particular type of component for a particular application; the system further comprising:
a locally deployed component configured to operate the algorithm for event detection created at the remote server for the particular type of component for the particular application while the locally deployed component is not connected to the remote server.

10. A method for detecting arcing, the method comprising:
recording data from a component, the data comprising:
measurements of one or more operating characteristics of the component over a period of time; and
a plurality of indications of system fault events;
receiving the data;
analyzing the data;
determining, if an event has occurred based at least in part on the received data; and
providing a notification of the event;
wherein the event comprises a micro arcing event in a plasma chamber,
wherein the component comprises a plasma generator.

11. The method of claim 10, further comprising:
transmitting the data from the component to a remote server,
wherein the determining is performed at the remote server.

12. The method of claim 10, further comprising:
recording data from a plurality of additional plasma generators; and
acquiring data from a plurality of additional data acquisition devices, and
wherein the data further comprises:
additional measurements from each of the plurality of additional plasma generators; and
additional indications of system faults from the plasma generator and additional plasma generators.

13. The method of claim 12, wherein at least some of the plurality of additional plasma generators are in different geographical locations.

14. The method of claim 10, wherein the determining is implemented by a machine learning program.

15. The method of claim 14, further comprising:
automatically developing, by the machine learning program, an algorithm to set a threshold for an operating point.

16. The method of claim 14, further comprising:
receiving, by the machine learning program, input from a user to assist in the determining.

17. The method of claim 10, and further comprising:
creating an algorithm for preventative maintenance at a remote server for a particular type of component for a particular application; and:
transferring the algorithm to a locally deployable component;
locally deploying the locally deployable component, and
operating the algorithm for event identification at the remote server for the particular type of component for the particular application while the locally deployable component is not connected to the remote server.

18. A non-transitory, tangible computer readable storage medium, encoded with processor readable instructions to perform a method for defining, identifying, or characterizing an event, the method comprising:
recording data from a component, the data comprising:
measurements of one or more operating characteristics of the component over a period of time; and
a plurality of indications of system fault events;
receiving the data;
analyzing the data;
determining, based on analysis of the measurements of the one or more operating characteristics and the system fault events, a threshold of an operating point, the operating point comprising:
the measurements of the one or more operating characteristics at a particular time;
wherein the threshold signifies a pending system fault event is probable to a defined degree of confidence within a specified window of time; and
providing a notification to perform preventative maintenance on the component.

19. The non-transitory, tangible computer readable storage medium of claim 18, the method further comprising:
recording data from a plurality of additional components; and
acquiring data from a plurality of additional data acquisition devices, and wherein the data further comprises:
additional measurements from each of the plurality of additional components; and
additional indications of system faults from each of the component and additional components.
